(19) United States
(12) Patent Application Publication
(10) Pub. No.: US 2025/0224707 A1
(43) Pub. Date: Jul. 10, 2025

(54) PREDICTING AND PRESENTING HAZARDOUS CONDITIONS OF MANUFACTURING EQUIPMENT

(71) Applicant: Applied Materials, Inc., Santa Clara, CA (US)

(72) Inventor: Rony David MATHEW, Kollam (IN)

(21) Appl. No.: 19/013,340

(22) Filed: Jan. 8, 2025

(30) Foreign Application Priority Data
Jan. 10, 2024 (IN) 202441001796

(51) Int. Cl. G05B 19/4069; G05B 19/18; G05B 19/4155; H01L 21/66

(52) U.S. Cl. CPC G05B 19/4069; G05B 19/188; G05B 19/4155; H01L 22/12; G05B 2219/35181; G05B 2219/35289; G05B 2219/35482

(57) ABSTRACT

A method includes obtaining first data indicative of a temperature of a first component of a process chamber. The method further includes processing the first data using a trained machine learning model. The trained machine learning model generates an output. The output includes second data, indicative of a temperature of a surface of the process chamber. The method further includes displaying an augmented reality overlay including a visual indication of the temperature of the surface to a user.

### RELATED APPLICATIONS

This application claims the benefit of Indian Application No. 202441001796, filed Jan. 10, 2024, entitled “PREDICTING AND PRESENTING HAZARDOUS CONDITIONS OF MANUFACTURING EQUIPMENT,” which is incorporated by reference herein.

### TECHNICAL FIELD

The present disclosure relates to methods associated with machine learning models used for assessment of manufactured devices, such as semiconductor devices. More particularly, the present disclosure relates to methods for predicting and presenting hazardous conditions of manufacturing equipment.

### BACKGROUND

Products may be produced by performing one or more manufacturing processes using manufacturing equipment. For example, semiconductor manufacturing equipment may be used to produce substrates via semiconductor manufacturing processes. Products are to be produced with particular properties, suited for a target application. Machine learning models are used in various process control and predictive functions associated with manufacturing equipment. Machine learning models are trained using data associated with the manufacturing equipment. One or more operations associated with manufacturing equipment may present a hazard to a user, such as high temperatures of a surface that may be contacted during a service or maintenance operation.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular embodiments of the disclosure or any scope of the claims. Its sole purpose is to present some concepts of the disclosure in a simplified form as a prelude to the more detailed description that is presented later.

In one aspect of the present disclosure, a method includes obtaining first data indicative of a temperature of a first component of a process chamber. The method further includes processing the first data using a trained machine learning model. The trained machine learning model generates an output. The output includes second data, indicative of a temperature of a surface of the process chamber. The method further includes displaying an augmented reality overlay including a visual indication of the temperature of the surface to a user.

In another aspect of the disclosure, a method includes obtaining first data indicative of a temperature of a first component of a process chamber in a first set of temperature conditions. The method further includes obtaining second data of a temperature of a surface of the process chamber at the first set of temperature conditions. The method further includes training a machine learning model to predict surface temperature of the process chamber by providing the first data as training input and the second data as target output.

In another aspect of the disclosure, a non-transitory machine-readable storage medium is disclosed. The storage medium stores instructions which, when executed, cause a processing device to perform operations. The operations include obtaining first data indicative of a temperature of a first component of a process chamber. The operations further include processing the first data using a trained machine learning model. The trained machine learning model generates an output. The output includes second data, indicative of a temperature of a surface of the process chamber. The operations further include displaying a visual indication of the temperature of the surface to a user.

### BRIEF DESCRIPTION OF THE DRAWINGS

The present disclosure is illustrated by way of example, and not by way of limitation in the figures of the accompanying drawings.

FIG. 1 is a block diagram illustrating an exemplary system architecture, according to some embodiments.

FIG. 2 depicts a block diagram of a system including an example data set generator for creating data sets for one or more supervised models, according to some embodiments.

FIG. 3 is a block diagram illustrating a system for generating output data, according to some embodiments.

FIG. 4A is a flow diagram of a method for generating a data set for a machine learning model, according to some embodiments.

FIG. 4B is a flow diagram of a method for generating and utilizing process chamber hazard data, according to some embodiments.

FIG. 4C is a flow diagram of a method for generating a trained machine learning model for determining hazard conditions of a process chamber, according to some embodiments.

FIG. 5 depicts various exterior surfaces of a process chamber, including a representation of the process chamber and a thermal overlay of the process chamber, according to some embodiments.

FIG. 6 is a block diagram illustrating a computer system, according to some embodiments.

### DETAILED DESCRIPTION

Described herein are technologies related to generating models for predicting temperatures of a process chamber, generating temperature data with one or more models, and presenting the temperature data to a user via an augmented reality interface. Manufacturing equipment is used to produce products, such as substrates (e.g., wafers, semiconductors). Manufacturing equipment may include a manufacturing or processing chamber to separate the substrate from the environment. The properties of produced substrates are to meet target values to facilitate specific functionalities. Manufacturing parameters are selected to produce substrates that meet the target property values. Many manufacturing parameters (e.g., hardware parameters, process parameters, etc.) contribute to the properties of processed substrates. Manufacturing systems may control parameters by specifying a set point for a property value and receiving data from sensors disposed within the manufacturing chamber, and making adjustments to the manufacturing equipment until the sensor readings match the set point. In some embodiments, trained machine learning models are utilized to improve performance of manufacturing equipment.

Use of manufacturing equipment, process tools, process equipment, and the like may include performance of maintenance actions in association with the equipment. For example, preventative maintenance may be performed periodically, or in response to one or more triggers, corrective maintenance may be performed in response to one or more faults of the manufacturing system, or the like. Some maintenance actions may be performed by the manufacturing equipment itself, such as some seasoning operations to adjust properties of material coating one or more interior surfaces of the process chamber, baking or cleaning operations designed to remove material from surfaces of the process chamber, etc. Some maintenance actions may be performed by a user. For example, a service technician, engineer, or the like may replace components, clean components, adjust components, or the like of a process chamber or manufacturing tool.

Performance of service operations by a user may introduce the user to one or more hazards associated with the manufacturing equipment. For example, components may have high electric charge, the equipment may include components capable of producing plasma discharge, mechanical parts such as robots may present a mechanical hazard, and various surfaces of a process chamber may be heated to temperatures high enough to risk burns. In some systems, some combination of protocols including interlocks, designated wait times, expensive and/or delicate infrared (IR) scanning equipment, or the like may be utilized for reducing risk to a user from hazards associated with service operations of manufacturing equipment.

Systems and methods of the present disclosure may address one or more shortcomings of conventional methods. Disclosed herein are methods and systems that may reduce the risk presented by hazards of a manufacturing system, for example during a service event of the manufacturing system.

In some embodiments, improvements to user interaction with a manufacturing system may include the use of machine learning models. Machine learning models may be applied in several ways associated with processing chambers and/or manufacturing equipment. A machine learning model may receive as input sensor data, measuring values of properties in a processing chamber. The machine learning model may be configured to predict hazardous conditions in association with a manufacturing system. The machine learning model may process the input data to predict hazards that may be encountered by a user interacting with a process chamber, process tool, or the like.

In some embodiments, a machine learning model may be utilized to provide an assessment of risk associated with a user interacting with manufacturing equipment, for example during a service event. A machine learning model (or more than one model) may be utilized to determine a level of risk, determine a level of hazard, provide a determination of whether risk is within an acceptable threshold to begin a service operation, or the like. In some embodiments, a machine learning model may be utilized to determine a temperature of one or more surfaces of a process chamber, such as exterior surfaces, surfaces likely to be touched by a user, surfaces associated with one or more service operations, or the like.

In some embodiments, data may be provided to a user indicating whether it is safe to proceed with a service operation. In some embodiments, data indicative of a condition of the process chamber, such as temperatures of one or more surfaces of the process chamber, may be provided to a user. In some embodiments, service may be enabled by such a system, such as by tripping an interlock allowing a user to open a chamber or adjust a component, or the like. For example, if an estimated temperature of one or more surface of a process chamber is below a temperature threshold, then an interlock may be automatically tripped.

In some embodiments, data associated with hazards of manufacturing equipment may be presented to a user via an augmented reality interface. Augmented reality, as used herein, refers to a technology that superimposes computer-generated information, such as text, images, or models, onto a real-world environment. An augmented reality (AR) device may include, for example, one or more cameras for assessing a real-world environment, and one or more displays for providing the augmented reality images to a user. Examples of augmented reality devices include AR glasses, a tablet computer or mobile phone (e.g., that includes a camera that captures images of a field of view of the camera and a display that outputs the captured images with an overlay of additional information. Virtual reality, e.g., creation by a processing device of an entirely artificial environment, may also be utilized in connection with this disclosure.

In some embodiments, augmented reality may be experienced through devices including screens and cameras, such as smartphones, tablets, or the like. Such devices may provide images of a real-world environment, along with augmented data. In some embodiments, augmented reality may be experienced through headset devices. In example, AR devices include devices that enable a user to observe a real-world environment through a display device, and overlay information via the display device. Augmented reality utilized with a headset-style device may seamlessly integrate digital content (e.g., based on output of a trained machine learning model) on a user's surroundings. The digital content may be indicative of hazards associated with manufacturing equipment, such as the status of one or more components of systems of the equipment, surface temperatures of one or more surfaces of the equipment, etc.

In some embodiments, an augmented reality headset may overlay or superimpose a representation of predicted temperature data over manufacturing equipment. For example, a heat-map style color scale may be overlaid to indicate to a user temperature of one or more surfaces of manufacturing equipment. A user may perform service operations upon indication that the manufacturing equipment is in a safe-to-service state.

In some embodiments, hazard data may be gathered from manufacturing equipment for training of a machine learning model for generating hazard predictions. For example, various temperature states of manufacturing equipment (e.g., states of various heat sources and heat sinks of the chamber, such as heaters, lamps, cooling plates, etc.) may be achieved and/or maintained, and temperature data of surfaces of interest taken (e.g., via an IR temperature scanning device) an utilized for training one or more models. In some embodiments, a physics-based model (e.g., computer engineering model) may be utilized for generating training data. In some embodiments, a combination of measurement data and physics-based model output data may be utilized for training a machine learning model to predict hazard states of manufacturing equipment.

In some embodiments, a machine learning model may be provided with data indicative of or related to a hazard condition of manufacturing equipment as input. For example, a state of one or more heaters, a state of one or more coolers, a previous temperature state of the chamber, etc., may be provided to a machine learning model for generating a prediction of current temperature of one or more surfaces of the manufacturing equipment. An augmented reality device may overlay temperature data on real-world images or the real-world manufacturing equipment for use by a user in determining whether to proceed with one or more operations (e.g., service operations) in association with the manufacturing equipment.

Systems and methods of the present disclosure provide advantages over conventional methods. Determining hazards through measurement may be difficult, cumbersome, expensive, time-consuming, or impossible. For example, IR thermal scanning devices may be expensive and/or delicate instruments, impractical for use with each service operation. Further, some hazards may be associated with components that are not available for measurements, such as surfaces within a process chamber. An augmented reality overlay may display indications provided by a trained machine learning model of hazards (e.g., temperatures) of conventionally inaccessible components of a manufacturing system. Further, displaying hazard-related data via an augmented reality device may enable a user to adjust one or more service operations in light of the presented data (e.g., avoid touching one surface in favor of another, safer surface), easily visually distinguish between different conditions of different components of manufacturing equipment, or the like.

In one aspect of the present disclosure, a method includes obtaining first data indicative of a temperature of a first component of a process chamber. The method further includes processing the first data using a trained machine learning model. The trained machine learning model generates an output. The output includes second data, indicative of a temperature of a surface of the process chamber. The method further includes displaying an augmented reality overlay including a visual indication of the temperature of the surface to a user.

In another aspect of the disclosure, a method includes obtaining first data indicative of a temperature of a first component of a process chamber in a first set of temperature conditions. The method further includes obtaining second data of a temperature of a surface of the process chamber at the first set of temperature conditions. The method further includes training a machine learning model to predict surface temperature of the process chamber by providing the first data as training input and the second data as target output.

In another aspect of the disclosure, a non-transitory machine-readable storage medium is disclosed. The storage medium stores instructions which, when executed, cause a processing device to perform operations. The operations include obtaining first data indicative of a temperature of a first component of a process chamber. The operations further include processing the first data using a trained machine learning model. The trained machine learning model generates an output. The output includes second data, indicative of a temperature of a surface of the process chamber. The operations further include displaying a visual indication of the temperature of the surface to a user.

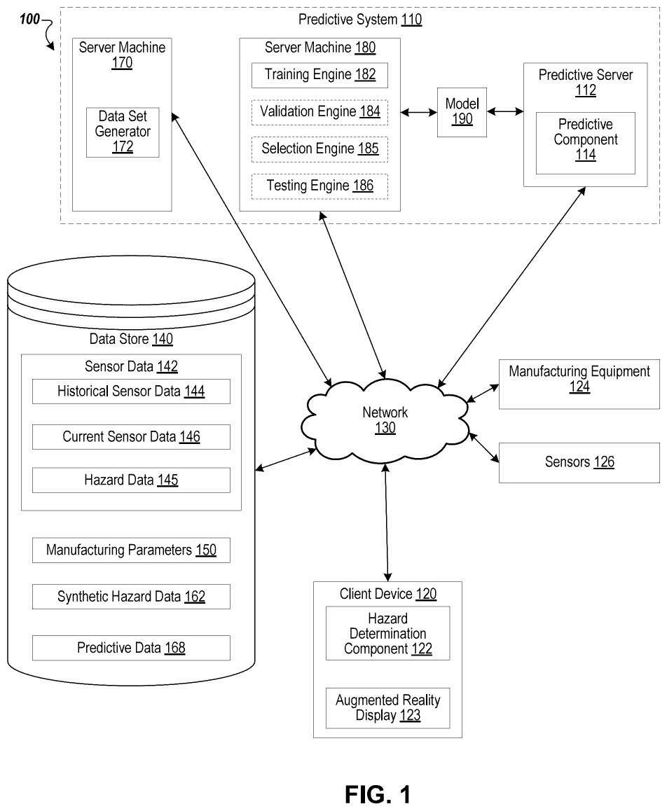

FIG. 1 is a block diagram illustrating an exemplary system 100 (exemplary system architecture), according to some embodiments. The system 100 includes a client device 120, manufacturing equipment 124, sensors 126, predictive server 112, and data store 140. The predictive server 112 may be part of predictive system 110. Predictive system 110 may further include server machines 170 and 180.

Sensors 126 may provide sensor data 142 associated with manufacturing equipment 124 (e.g., associated with producing, by manufacturing equipment 124, corresponding products, such as substrates). Sensor data 142 may be used to ascertain equipment health and/or product health (e.g., product quality). Sensor data 142 may be used to ascertain equipment hazards, e.g., sensor data 142 may include hazard data 145. Hazard data 145 may include data indicative of risks associated with interacting with, servicing, adjusting, opening, cleaning, or the like the manufacturing equipment. In some embodiments, hazard data 145 may include measured temperature data of one or more surfaces of a manufacturing system that may be touched by a technician during a service operation. Hazard data may be generated by a sensor 126 that is not included as a part of manufacturing equipment 124, is not integrated with manufacturing equipment 124, etc. For example, hazard data 145 may be generated by an infrared (IR) scanner to determine temperatures of surfaces of a process chamber, manufacturing tool, or the like.

Manufacturing equipment 124 may produce products following a recipe or performing runs over a period of time. In some embodiments, sensor data 142 may include values of one or more of optical sensor data, spectral data, temperature (e.g., heater temperature), spacing (SP), pressure, High Frequency Radio Frequency (HFRF), radio frequency (RF) match voltage, RF match current, RF match capacitor position, voltage of Electrostatic Chuck (ESC), actuator position, electrical current, flow, power, voltage, etc. Sensor data 142 may include historical sensor data 144 and current sensor data 146. Current sensor data 146 may be associated with a product currently being processed, a product recently processed, a number of recently processed products, etc. Current sensor data 146 may be used as input to a trained machine learning model, e.g., to generate predictive data 168. Historical sensor data 144 may include data stored associated with previously produced products. Historical sensor data 144 may be used to train a machine learning model, e.g., model 190. Historical sensor data 144 and/or current sensor data 146 may include attribute data, e.g., labels of manufacturing equipment ID or design, sensor ID, type, and/or location, label of a state of manufacturing equipment, such as a present fault, service lifetime, etc.

Sensor data 142 may be associated with or indicative of manufacturing parameters such as hardware parameters (e.g., hardware settings or installed components, e.g., size, type, etc.) of manufacturing equipment 124 or process parameters (e.g., heater settings, gas flow, etc.) of manufacturing equipment 124. Data associated with some hardware parameters and/or process parameters may, instead or additionally, be stored as manufacturing parameters 150, which may include historical manufacturing parameters (e.g., associated with historical processing runs) and current manufacturing parameters. Manufacturing parameters 150 may be indicative of input settings to the manufacturing device (e.g., heater power, gas flow, etc.). Sensor data 142 and/or manufacturing parameters 150 may be provided while the manufacturing equipment 124 is performing manufacturing processes (e.g., equipment readings while processing products) and/or after such processes are complete.

In some embodiments, sensor data 142, or manufacturing parameters 150 may be processed (e.g., by the client device 120 and/or by the predictive server 112). Processing of the sensor data 142 may include generating features. In some embodiments, the features are a pattern in the sensor data 142, and/or manufacturing parameters 150 (e.g., slope, width, height, peak, etc.) or a combination of values from the sensor data 142 and/or manufacturing parameters (e.g., power delivered to a heater derived from voltage and current, etc.). Sensor data 142 may include features and the features may be used by predictive component 114 for performing signal processing and/or for obtaining predictive data 168. Sensor data 142 may be processed for determination of hazards associated with a process chamber. Sensor data 142 may be processed for performance of one or more actions to reduce risk presented by hazards to a user. Sensor data 142 may be processed for performance of a risk reduction action.

Each instance (e.g., set) of sensor data 142 may correspond to a target substrate processing operation, type of operation, a set of manufacturing equipment, a type of substrate produced by manufacturing equipment, or the like. Each instance of manufacturing parameters 150 may likewise correspond to a type or operation, a set of manufacturing equipment, a type of substrate produced by manufacturing equipment, or the like. The data store may further store information associating sets of different data types, e.g., information indicative that a set of sensor data and a set of manufacturing parameters are all associated with the same product, type or model of manufacturing equipment, type of substrate, etc.

In some embodiments, predictive system 110 may generate predictive data 168 using supervised machine learning (e.g., predictive data 168 includes output from a machine learning model that was trained using labeled data, such as sensor data or manufacturing parameter data labeled with hazard data. In some embodiments, predictive system 110 may generate predictive data 168 using unsupervised machine learning (e.g., predictive data 168 includes output from a machine learning model that was trained using unlabeled data, output may include clustering results, principle component analysis, anomaly detection, etc.). In some embodiments, predictive system 110 may generate predictive data 168 using semi-supervised learning (e.g., training data may include a mix of labeled and unlabeled data, etc.).

Client device 120, manufacturing equipment 124, sensors 126, predictive server 112, data store 140, server machine 170, and server machine 180 may be coupled to each other via network 130 for generating predictive data 168, e.g., to perform risk reduction actions. In some embodiments, network 130 may provide access to cloud-based services. Operations performed by client device 120, predictive system 110, data store 140, etc., may be performed by virtual cloud-based devices.

In some embodiments, network 130 is a public network that provides client device 120 with access to the predictive server 112, data store 140, and other publicly available computing devices. In some embodiments, network 130 is a private network that provides client device 120 access to manufacturing equipment 124, sensors 126, data store 140, and other privately available computing devices. Network 130 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

Client device 120 may include computing devices such as Personal Computers (PCs), laptops, mobile phones, smart phones, tablet computers, netbook computers, network connected televisions (“smart TV”), network-connected media players (e.g., Blu-ray player), a set-top-box, Over-the-Top (OTT) streaming devices, operator boxes, augmented reality devices, augmented or virtual reality headsets, etc. Client device 120 may include a hazard determination component 122. Hazard determination component 122 may receive user input (e.g., via a Graphical User Interface (GUI) displayed via the client device 120) of an indication associated with manufacturing equipment 124. In some embodiments, hazard determination component 122 transmits the indication to the predictive system 110, receives output (e.g., predictive data 168) from the predictive system 110, determines one or more actions to perform in view of hazards associated with the process chamber based on the output, and causes the actions to be implemented. Actions implemented by hazard determination component 122 may include displaying indications of hazards, such as overlaying predicted temperature data via an AR display. Actions implemented by hazard determination component 122 may include manipulating one or more safety features of a process chamber, such as engaging a lock to protect a user from a hazardous condition. In some embodiments, hazard determination component 122 obtains sensor data 142 (e.g., current sensor data 146) associated with manufacturing equipment 124 (e.g., from data store 140, etc.) and provides sensor data 142 (e.g., current sensor data 146) associated with the manufacturing equipment 124 to predictive system 110. In some embodiments, client device 120 may utilized an augmented reality display 123 (and/or a virtual reality display) to provide information to a user, receive input from a user, etc. Client device 120 may display data indicative of risks associated with manufacturing equipment 124 to a user.

In some embodiments, hazard determination component 122 stores data to be used as input to a machine learning or other model (e.g., current sensor data 146 to be provided to model 190) in data store 140 and a component of predictive system 110 (e.g., predictive server 112, server machine 170) retrieves sensor data 142 from data store 140. In some embodiments, predictive server 112 may store output (e.g., predictive data 168) of the trained model(s) 190 in data store 140 and client device 120 may retrieve the output from data store 140.

In some embodiments, hazard determination component 122 receives an indication of an action to be taken in association with chamber hazards from the predictive system 110 and causes the action to be implemented. Each client device 120 may include an operating system that allows users to one or more of generate, view, or edit data (e.g., indication associated with manufacturing equipment 124, risk reduction actions associated with manufacturing equipment 124, etc.).

In some embodiments, predictive data 168 may include predictions of hazards associated with manufacturing equipment 124, such as conditions of equipment that may present risk to a user, technician, or the like interacting with manufacturing equipment 124. Hazard data 145 may be or include measured data of hazards of manufacturing equipment 124, such as temperature of one or more surfaces of the equipment, electrical charge carried by one or more components of manufacturing equipment 124, or the like. Predictive data 168 may include predictions of hazardous conditions in association with manufacturing equipment 124. Predictive data 168 may be generated by a trained machine learning model. Predictive data 168 may be based on sensor data, manufacturing parameters, ambient conditions, one or more durations of time, etc. Synthetic hazard data 162 may include computer-generated data of hazards associated with manufacturing equipment 124. Synthetic hazard data 162 may be generated by one or more physics-based models. In some embodiments, hazard data 145 may be utilized for calibration of one or more physics-based models for generation of synthetic hazard data 162. Hazard data 145 and/or synthetic hazard data 162 may be utilized in training one or more machine learning models for generating predictive data 168.

Performance of operations in association with manufacturing equipment 124 may include risks, hazards, or the like. For example, performance by a technician of service operations such as cleaning, component replacement, or other service operations may present hazards to the technician. By providing input data to model 190, obtaining predictive data 168 indicative of hazards, and presenting them to a user (e.g., via augmented reality display 123), a user may be informed of one or more hazards to be avoided, fewer users may be injured by hazardous conditions of manufacturing equipment 124, fewer resources may be lost to user injury, downtime, or the like.

Types of actions that may be performed by system 100 in association with predicted hazards include augmented reality display, virtual reality display, safety interlock, model-based process control, reducing risk to technicians during preventative operative maintenance, reducing risk to technicians during corrective maintenance, design optimization for reducing hazardous conditions, updating of manufacturing parameters, updating manufacturing recipes, feedback control, machine learning modification, or the like.

In some embodiments, the action includes providing an alert (e.g., an alarm to stop or not perform a service process if the predictive data 168 indicates a predicted abnormality, such as a hazardous condition, an abnormality of a component or manufacturing equipment 124, or the like). In some embodiments, a machine learning model may be trained to predict hazardous conditions. For example, a machine learning model may be trained to predict surface temperatures of surfaces of a process chamber, such as surfaces likely to be touched by a user during a service procedure. The machine learning model may provide the predicted surface temperatures to client device 120, which may present them to a user (e.g., by providing a thermal overlay of the process chamber via augmented reality display 123). A risk reduction action in association with a chamber hazard may include providing an interlock signal (e.g., locking one or more chamber components until a safe condition is achieved), providing information to a user via augmented reality, or the like. In some embodiments performance of a risk reduction action may include retraining a machine learning model associated with manufacturing equipment 124. In some embodiments, performance of a risk reduction action may include training a new machine learning model associated with manufacturing equipment 124.

Predictive server 112, server machine 170, and server machine 180 may each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc. Operations of predictive server 112, server machine 170, server machine 180, data store 140, etc., may be performed by a cloud computing service, cloud data storage service, etc.

Predictive server 112 may include a predictive component 114. In some embodiments, the predictive component 114 may receive current sensor data 146, and/or current manufacturing parameters (e.g., receive from the client device 120, retrieve from the data store 140) and generate output (e.g., predictive data 168) for performing risk reduction action associated with the manufacturing equipment 124 based on the current data. In some embodiments, predictive data 168 may include one or more predicted hazards of manufacturing equipment. In some embodiments, predictive component 114 may use one or more trained machine learning models 190 to determine the output for performing one or more actions in association with chamber hazards based on current data.

Manufacturing equipment 124 may be associated with one or more machine leaning models, e.g., model 190. Machine learning models associated with manufacturing equipment 124 may perform many tasks, including process control, classification, performance predictions, hazard prediction, etc. Model 190 may be trained using data associated with manufacturing equipment 124 or products processed by manufacturing equipment 124, e.g., sensor data 142 (e.g., collected by sensors 126), manufacturing parameters 150 (e.g., associated with process control of manufacturing equipment 124), etc.

One type of machine learning model that may be used to perform some or all of the above tasks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs).

A recurrent neural network (RNN) is another type of machine learning model. A recurrent neural network model is designed to interpret a series of inputs where inputs are intrinsically related to one another, e.g., time trace data, sequential data, etc. Output of a perceptron of an RNN is fed back into the perceptron as input, to generate the next output.

Deep learning is a class of machine learning algorithms that use a cascade of multiple layers of nonlinear processing units for feature extraction and transformation. Each successive layer uses the output from the previous layer as input. Deep neural networks may learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. In an image recognition application, for example, the raw input may be a matrix of pixels; the first representational layer may abstract the pixels and encode edges; the second layer may compose and encode arrangements of edges; the third layer may encode higher level shapes (e.g., teeth, lips, gums, etc.); and the fourth layer may recognize a scanning role. Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs may be that of the network and may be the number of hidden layers plus one. For recurrent neural networks, in which a signal may propagate through a layer more than once, the CAP depth is potentially unlimited.

In some embodiments, predictive component 114 receives current sensor data 146 and/or current manufacturing parameters, performs signal processing to break down the current data into sets of current data, provides the sets of current data as input to a trained model 190, and obtains outputs indicative of predictive data 168 from the trained model 190. In some embodiments, predictive component 114 receives data related to hazards present in a chamber (e.g., data indicative of one or more heat sources such as heater temperature settings or lamp settings, data associated with cooling sources such as cooling fluid flow or temperature, data associated with component electrical charge such as capacitor characteristics, voltages, etc.) and provide the data to a trained model 190. The trained model 190 may generate output indicative of predictions of hazardous conditions of manufacturing equipment 124, e.g., for display via augmented reality display 123.

In some embodiments, the various models discussed in connection with model 190 (e.g., supervised machine learning model, unsupervised machine learning model, etc.) may be combined in one model (e.g., an ensemble model), or may be separate models.

Data may be passed back and forth between several distinct models included in model 190 and predictive component 114. In some embodiments, some or all of these operations may instead be performed by a different device, e.g., client device 120, server machine 170, server machine 180, etc. It will be understood by one of ordinary skill in the art that variations in data flow, which components perform which processes, which models are provided with which data, and the like are within the scope of this disclosure.

Data store 140 may be a memory (e.g., random access memory), a drive (e.g., a hard drive, a flash drive), a database system, a cloud-accessible memory system, or another type of component or device capable of storing data. Data store 140 may include multiple storage components (e.g., multiple drives or multiple databases) that may span multiple computing devices (e.g., multiple server computers). The data store 140 may store sensor data 142, manufacturing parameters 150, synthetic hazard data 162, and predictive data 168.

Sensor data 142 may include historical sensor data 144 and current sensor data 146. Sensor data may include sensor data time traces over the duration of manufacturing processes, associations of data with physical sensors, pre-processed data, such as averages and composite data, and data indicative of sensor performance over time (i.e., many manufacturing processes). Manufacturing parameters 150 may contain similar features. Historical sensor data, and historical manufacturing parameters may be historical data (e.g., at least a portion of these data may be used for training model 190). Current sensor data 146, may be current data (e.g., at least a portion to be input into learning model 190, subsequent to the historical data) for which predictive data 168 is to be generated (e.g., for performing risk reduction actions). Synthetic hazard data 162 may include synthetic data generated with computer assistance (e.g., via one or more physics-based models, digital twin models, etc.) which may be used for training machine learning models for predicting hazard conditions.

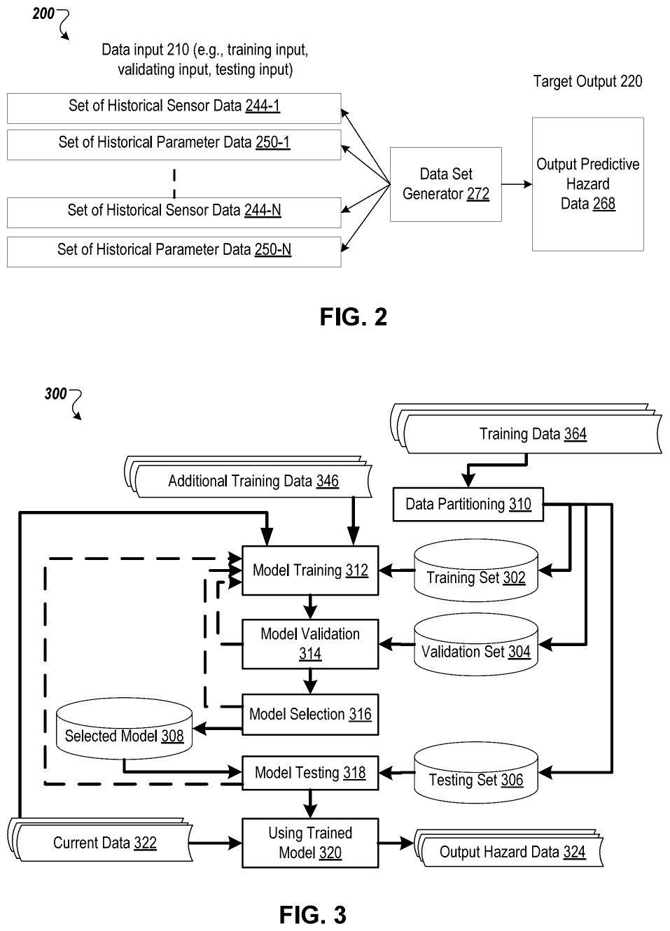

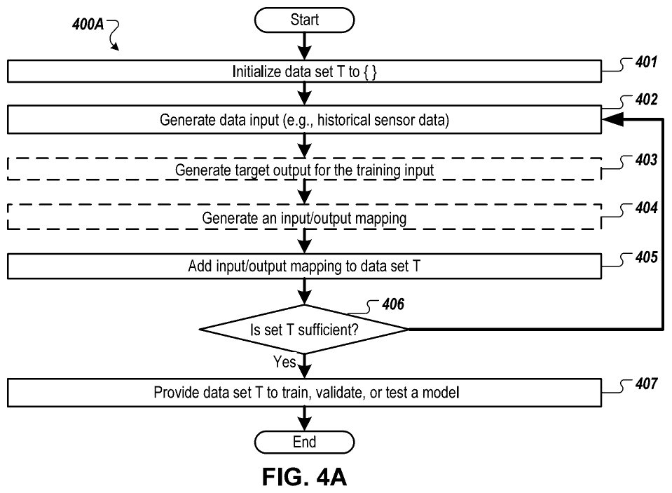

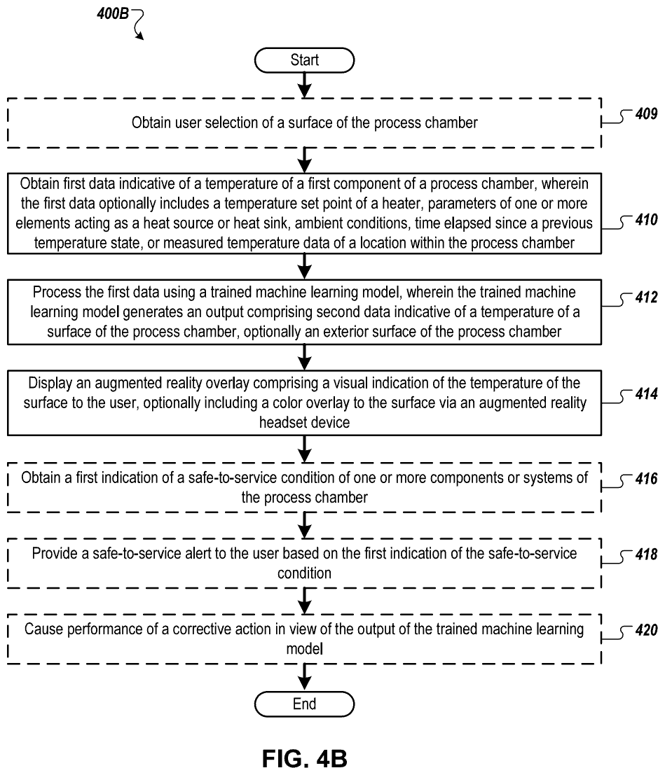

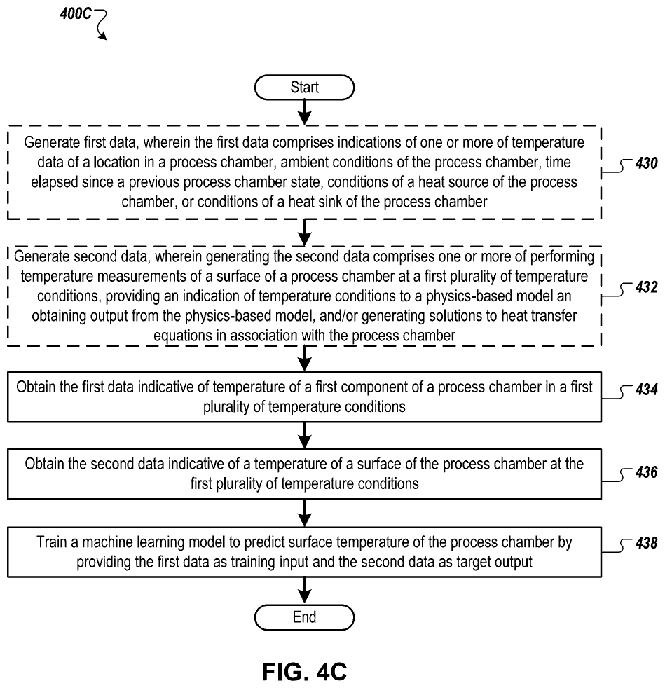

In some embodiments, predictive system 110 further includes server machine 170 and server machine 180. Server machine 170 includes a data set generator 172 that is capable of generating data sets (e.g., a set of data inputs and a set of target outputs) to train, validate, and/or test model(s) 190, including one or more machine learning models. Some operations of data set generator 172 are described in detail below with respect to FIGS. 2 and 4A. In some embodiments, data set generator 172 may partition the historical data (e.g., historical sensor data 144, historical manufacturing parameters) into a training set (e.g., sixty percent of the historical data), a validating set (e.g., twenty percent of the historical data), and a testing set (e.g., twenty percent of the historical data).

In some embodiments, predictive system 110 (e.g., via predictive component 114) generates multiple sets of features. For example a first set of features may correspond to a first set of types of sensor data (e.g., from a first set of sensors, first combination of values from first set of sensors, first patterns in the values from the first set of sensors) that correspond to each of the data sets (e.g., training set, validation set, and testing set) and a second set of features may correspond to a second set of types of sensor data (e.g., from a second set of sensors different from the first set of sensors, second combination of values different from the first combination, second patterns different from the first patterns) that correspond to each of the data sets.

In some embodiments, machine learning model 190 is provided historical data as training data. In some embodiments, machine learning model 190 is provided synthetic hazard data 162 as training data. The type of data provided will vary depending on the intended use of the machine learning model. For example, a machine learning model may be trained by providing the model with historical sensor data 144 as training input and corresponding hazard data (e.g., surface temperature data) as target output. In some embodiments, a large volume of data is used to train model 190, e.g., sensor and synthetic data of hundreds of iterations, conditions, or the like may be used. In some embodiments, a fairly small volume of data is available to train model 190, e.g., model 190 is to be trained to recognize a rare event such as equipment failure, model 190 is to be trained to generate predictions of a newly seasoned or maintained chamber, etc. Synthetic hazard data 162 may be generated by a physics-based model, digital twin model, or the like to augment available measured hazard data 145 data in training model 190.

Server machine 180 includes a training engine 182, a validation engine 184, selection engine 185, and/or a testing engine 186. An engine (e.g., training engine 182, a validation engine 184, selection engine 185, and a testing engine 186) may refer to hardware (e.g., circuitry, dedicated logic, programmable logic, microcode, processing device, etc.), software (such as instructions run on a processing device, a general purpose computer system, or a dedicated machine), firmware, microcode, or a combination thereof. The training engine 182 may be capable of training a model 190 and/or synthetic data generator 174 using one or more sets of features associated with the training set from data set generator 172. The training engine 182 may generate multiple trained models 190, where each trained model 190 corresponds to a distinct set of features of the training set (e.g., sensor data from a distinct set of sensors). For example, a first trained model may have been trained using all features (e.g., X1-X5), a second trained model may have been trained using a first subset of the features (e.g., X1, X2, X4), and a third trained model may have been trained using a second subset of the features (e.g., X1, X3, X4, and X5) that may partially overlap the first subset of features. Data set generator 172 may receive the output of a model (e.g., a physics-based model generating synthetic hazard data 162), collect that data into training, validation, and testing data sets, and use the data sets to train a second model (e.g., a machine learning model configured to output predictive data 168, recommended actions, etc.).

Validation engine 184 may be capable of validating a trained model 190 using a corresponding set of features of the validation set from data set generator 172. For example, a first trained machine learning model 190 that was trained using a first set of features of the training set may be validated using the first set of features of the validation set. The validation engine 184 may determine an accuracy of each of the trained models 190 based on the corresponding sets of features of the validation set. Validation engine 184 may discard trained models 190 that have an accuracy that does not meet a threshold accuracy. In some embodiments, selection engine 185 may be capable of selecting one or more trained models 190 that have an accuracy that meets a threshold accuracy. In some embodiments, selection engine 185 may be capable of selecting the trained model 190 that has the highest accuracy of the trained models 190.

Testing engine 186 may be capable of testing a trained model 190 using a corresponding set of features of a testing set from data set generator 172. For example, a first trained machine learning model 190 that was trained using a first set of features of the training set may be tested using the first set of features of the testing set. Testing engine 186 may determine a trained model 190 that has the highest accuracy of all of the trained models based on the testing sets.

In the case of a machine learning model, model 190 may refer to the model artifact that is created by training engine 182 using a training set that includes data inputs and corresponding target outputs (correct answers for respective training inputs). Patterns in the data sets can be found that map the data input to the target output (the correct answer), and machine learning model 190 is provided mappings that capture these patterns. The machine learning model 190 may use one or more of Support Vector Machine (SVM), Radial Basis Function (RBF), clustering, supervised machine learning, semi-supervised machine learning, unsupervised machine learning, k-Nearest Neighbor algorithm (k-NN), linear regression, random forest, neural network (e.g., artificial neural network, recurrent neural network), etc.

In some embodiments, one or more machine learning models 190 may be trained using historical data (e.g., historical sensor data 144). In some embodiments, models 190 may have been trained using synthetic hazard data 162, or a combination of historical data and synthetic data.

In some embodiments, a physics-based model for generating synthetic hazard data 162 may be calibrated, verified, tested, and/or adjusted based on measured hazard data 145. For example, a physics-based model may be generated based on heat transfer properties of a process chamber, electrical properties of components of the process chamber, etc. Iterations of input conditions to the physics-based model may be tested on a corresponding physical chamber, and hazard output (e.g., surface temperatures) measured and compared to predictions of the physics-based model. One or more parameters of the physics-based model may be adjusted to improve accuracy of synthetic hazard data 162 generated by the physics-based model.

Predictive component 114 may provide current data to model 190 and may run model 190 on the input to obtain one or more outputs. For example, predictive component 114 may provide current sensor data 146 to model 190 and may run model 190 on the input to obtain one or more outputs. Predictive component 114 may be capable of determining (e.g., extracting) predictive data 168 from the output of model 190. Predictive component 114 may determine (e.g., extract) confidence data from the output that indicates a level of confidence that predictive data 168 is an accurate predictor of a process associated with the input data for products produced or to be produced using the manufacturing equipment 124 at the current sensor data 146 and/or current manufacturing parameters. Predictive component 114 or hazard determination component 122 may use the confidence data to decide whether to cause performance of an action associated with the manufacturing equipment 124 based on predictive data 168.

The confidence data may include or indicate a level of confidence that the predictive data 168 is an accurate prediction for products or components associated with at least a portion of the input data. In one example, the level of confidence is a real number between 0 and 1 inclusive, where 0 indicates no confidence that the predictive data 168 is an accurate prediction for products processed according to input data or component health of components of manufacturing equipment 124 and 1 indicates absolute confidence that the predictive data 168 accurately predicts properties of products processed according to input data or component health of components of manufacturing equipment 124. Responsive to the confidence data indicating a level of confidence below a threshold level for a predetermined number of instances (e.g., percentage of instances, frequency of instances, total number of instances, etc.) predictive component 114 may cause trained model 190 to be re-trained (e.g., based on current sensor data 146, current manufacturing parameters, etc.). In some embodiments, retraining may include generating one or more data sets (e.g., via data set generator 172) utilizing historical data and/or synthetic data.

For purpose of illustration, rather than limitation, aspects of the disclosure describe the training of one or more machine learning models 190 using historical data (e.g., historical sensor data 144, historical manufacturing parameters) and synthetic data 162 and inputting current data (e.g., current sensor data 146 and/or current manufacturing parameters) into the one or more trained machine learning models to determine predictive data 168. In other embodiments, a heuristic model, physics-based model, or rule-based model is used to determine predictive data 168 (e.g., without using a trained machine learning model). In some embodiments, such models may be trained using historical and/or synthetic data. In some embodiments, these models may be retrained utilizing a combination of true historical data and synthetic data. Predictive component 114 may monitor historical sensor data 144 and/or historical manufacturing parameters. Any of the information described with respect to data inputs 210 of FIG. 2 may be monitored or otherwise used in the heuristic, physics-based, or rule-based model.

In some embodiments, the functions of client device 120, predictive server 112, server machine 170, and server machine 180 may be provided by a fewer number of machines. For example, in some embodiments server machines 170 and 180 may be integrated into a single machine, while in some other embodiments, server machine 170, server machine 180, and predictive server 112 may be integrated into a single machine. In some embodiments, client device 120 and predictive server 112 may be integrated into a single machine. In some embodiments, functions of client device 120, predictive server 112, server machine 170, server machine 180, and data store 140 may be performed by a cloud-based service.

In general, functions described in one embodiment as being performed by client device 120, predictive server 112, server machine 170, and server machine 180 can also be performed on predictive server 112 in other embodiments, if appropriate. In addition, the functionality attributed to a particular component can be performed by different or multiple components operating together. For example, in some embodiments, the predictive server 112 may determine that an action is to be performed based on the predictive data 168. In another example, client device 120 may determine the predictive data 168 based on output from the trained machine learning model.

In addition, the functions of a particular component can be performed by different or multiple components operating together. One or more of the predictive server 112, server machine 170, or server machine 180 may be accessed as a service provided to other systems or devices through appropriate application programming interfaces (API).

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

FIG. 2 depicts a block diagram of example data set generator 272 (e.g., data set generator 172 of FIG. 1) to create data sets for training, testing, validating, etc. a model (e.g., model 190 of FIG. 1), according to some embodiments. Data set generator 272 may be part of server machine 170 of FIG. 1. In some embodiments, several machine learning models associated with manufacturing equipment 124 may be trained, used, and maintained (e.g., within a manufacturing facility). Each machine learning model may be associated with one data set generators 272, multiple machine learning models may share a data set generator 272, etc.

FIG. 2A depicts a system 200 including data set generator 272 for creating data sets for one or more supervised models (e.g., model 190 of FIG. 1). Data set generator 272 may create data sets (e.g., data input 210, target output 220) using historical data, sensor data, manufacturing equipment parameter data, hazard data, and/or synthetic hazard data. In some embodiments, a data set generator similar to data set generator 272 may be utilized to train an unsupervised machine learning model, e.g., target output 220 may not be generated by data set generator 272.

Data set generator 272 may generate data sets to train, test, and validate a model. In some embodiments, data set generator 272 may generate data sets for a machine learning model. In some embodiments, data set generator 272 may generate data sets for training, testing, and/or validating a model configured to generate predictive data indicative of hazards of a manufacturing system. The machine learning model is provided with set of historical sensor data 244-1 and/or set of historical parameter data 250-1. The sensor data may include data from sensors indicative of potential hazards of the manufacturing equipment, such as temperature readings from one or more temperature sensors of the chamber. The historical parameter data may include set points, chamber conditions, or other parameters related to hazards of the manufacturing equipment, such as set points of one or more heat sources included in the chamber. In some embodiments, at least a portion of the historical sensor data and/or historical parameter data may be synthetic, e.g., may be input to a calibrated physics-based model that is utilized to derive synthetic hazard data.

Data set generator 272 may be used to generate data for any type of machine learning model that takes as input sensor and/or equipment parameter data. Data set generator 272 may be used to generate data for a machine learning model that generates predicted metrology data of a substrate. Data set generator 272 may be used to generate data for a machine learning model configured to provide process control instructions. Data set generator 272 may be used to generate data for a machine learning model configured to identify a product anomaly and/or processing equipment fault. Data set generator 272 may be used to generate data for a machine learning model that predicts hazards and/or recommends hazard or risk reduction actions in association with a manufacturing chamber.

In some embodiments, data set generator 272 generates a data set (e.g., training set, validating set, testing set) that includes one or more data inputs 210 (e.g., training input, validating input, testing input). Data inputs 210 may be provided to training engine 182, validating engine 184, or testing engine 186. The data set may be used to train, validate, or test the model (e.g., model 190 of FIG. 1).

In some embodiments, data input 210 may include one or more sets of data. As an example, system 200 may produce sets of sensor data that may include one or more of sensor data from one or more types of sensors, combinations of sensor data from one or more types of sensors, patterns from sensor data from one or more types of sensors, and/or synthetic versions thereof.

In some embodiments, data set generator 272 may generate a first data input corresponding to a first set of historical sensor data 244-1 and/or first set of historical parameter data 250-1 to train, validate, or test a first machine learning model. Data set generator 272 may generate a second data input corresponding to a second set of historical data to train, validate, or test a second machine learning model. Further sets of historical sensor and/or parameter data may further be utilized in generating further machine learning models. Any number of sets of historical data may be utilized in generating any number of machine learning models, up to a final set, set of historical sensor data 244-N and/or final set of historical parameter data 250-N (N representing any target quantity of data sets, models, etc.).

In some embodiments, data set generator 272 may generate a first data input corresponding to a first set of historical sensor data 244-1 and/or first set of historical parameter data 250-1 to train, validate, or test a first machine learning model. Data set generator 272 may generate a second data input corresponding to a second set of historical data to train, validate, or test a second machine learning model.

In some embodiments, data set generator 272 generates a data set (e.g., training set, validating set, testing set) that includes one or more data inputs 210 (e.g., training input, validating input, testing input) and may include one or more target outputs 220 that correspond to the data inputs 210. The data set may also include mapping data that maps the data inputs 210 to the target outputs 220. In some embodiments, data set generator 272 may generate data for training a machine learning model configured to output predictive hazard data 268 in association with a state of a manufacturing system, such as indicating hazards that may be encountered by a technician performing a service operation of the manufacturing equipment. In some embodiments, temperatures of one or more surfaces of a process tool may be predicted by the model. For such a model, target output 220 may include output data indicative of predicted surface temperatures. In some embodiments, other hazards such as electrical charge, robot position, moving component speed, or the like may be predicted by the model.

In some embodiments, subsequent to generating a data set and training, validating, or testing a machine learning model using the data set, the model may be further trained, validated, or tested, or adjusted (e.g., adjusting weights or parameters associated with input data of the model, such as connection weights in a neural network).

FIG. 3 is a block diagram illustrating system 300 for generating output data (e.g., synthetic data 162 of FIG. 1), according to some embodiments. In some embodiments, system 300 may be used in conjunction with a machine learning model configured to generate predictive hazard data (e.g., model 190 of FIG. 1). In some embodiments, system 300 may be used in conjunction with a machine learning model to determine a risk reduction action associated with manufacturing equipment. In some embodiments, system 300 may be used in conjunction with a machine learning model to determine a fault of manufacturing equipment. System 300 may be used in conjunction with a machine learning model with a different function than those listed, associated with a manufacturing system.

At block 310, system 300 (e.g., components of predictive system 110 of FIG. 1) performs data partitioning (e.g., via data set generator 172 of server machine 170 of FIG. 1) of data to be used in training, validating, and/or testing a machine learning model. In some embodiments, training data 364 includes historical data, such as historical sensor data, historical process chamber component parameter data (e.g., component temperature set-points), measured historical hazard data, etc. In some embodiments, training data 364 may include data associated with hazards of a process chamber, such as data indicating contributions to hazards, data measuring chamber hazards, etc. For example, training data 364 may include process chamber parameters or sensor data that are indicative of hazardous conditions. Training data 364 may further include measurements of the hazards associated with the chamber parameters and/or sensor data. In some embodiments, synthetic data may be utilized, e.g., process chamber conditions may be provided to a physics-based model, and predictions of hazards may be generated by the physics-based model. In some embodiments, performing physics-based modeling may be impractical in real time, as it may be slow and/or computationally expensive. However, output of a physics-based model may be utilized to train a machine learning model, which may be efficient enough to be used for real-time hazard assessment and reporting.

Training data 364 may undergo data partitioning at block 310 to generate training set 302, validation set 304, and testing set 306. For example, the training set may be 60% of the training data, the validation set may be 20% of the training data, and the testing set may be 20% of the training data.

The generation of training set 302, validation set 304, and testing set 306 may be tailored for a particular application. For example, the training set may be 60% of the training data, the validation set may be 20% of the training data, and the testing set may be 20% of the training data. System 300 may generate a plurality of sets of features for each of the training set, the validation set, and the testing set. For example, if training data 364 includes sensor data, including features derived from sensor data from 20 sensors (e.g., sensors 126 of FIG. 1) and 10 manufacturing parameters (e.g., manufacturing parameters that correspond to the same processing runs(s) as the sensor data from the 20 sensors), the sensor data may be divided into a first set of features including sensors 1-10 and a second set of features including sensors 11-20. The manufacturing parameters may also be divided into sets, for instance a first set of manufacturing parameters including parameters 1-5, and a second set of manufacturing parameters including parameters 6-10. Either target input, target output, both, or neither may be divided into sets. Multiple models may be trained on different sets of data.

At block 312, system 300 performs model training (e.g., via training engine 182 of FIG. 1) using training set 302. Training of a machine learning model and/or of a physics-based model (e.g., a digital twin) may be achieved in a supervised learning manner, which involves providing a training dataset including labeled inputs through the model, observing its outputs, defining an error (by measuring the difference between the outputs and the label values), and using techniques such as deep gradient descent and backpropagation to tune the weights of the model such that the error is minimized. In many applications, repeating this process across the many labeled inputs in the training dataset yields a model that can produce correct output when presented with inputs that are different than the ones present in the training dataset. In some embodiments, training of a machine learning model may be achieved in an unsupervised manner, e.g., labels or classifications may not be supplied during training. An unsupervised model may be configured to perform anomaly detection, result clustering, etc.

For each training data item in the training dataset, the training data item may be input into the model (e.g., into the machine learning model). The model may then process the input training data item (e.g., a number of process chamber parameters, sensor readings, reports on ambient conditions or time durations, etc.) to generate an output. The output may include, for example, predictive hazard data. The output may be compared to a label of the training data item (e.g., a measured or synthetic assessment of hazards associated with the input data).

Processing logic may then compare the generated output (e.g., predictive hazard data) to the label (e.g., measured and/or synthetic hazard data) that was included in the training data item. Processing logic determines an error (i.e., a classification error) based on the differences between the output and the label(s). Processing logic adjusts one or more weights and/or values of the model based on the error.

In the case of training a neural network, an error term or delta may be determined for each node in the artificial neural network. Based on this error, the artificial neural network adjusts one or more of its parameters for one or more of its nodes (the weights for one or more inputs of a node). Parameters may be updated in a back propagation manner, such that nodes at a highest layer are updated first, followed by nodes at a next layer, and so on. An artificial neural network contains multiple layers of “neurons”, where each layer receives as input values from neurons at a previous layer. The parameters for each neuron include weights associated with the values that are received from each of the neurons at a previous layer. Accordingly, adjusting the parameters may include adjusting the weights assigned to each of the inputs for one or more neurons at one or more layers in the artificial neural network.

System 300 may train multiple models using multiple sets of features of the training set 302 (e.g., a first set of features of the training set 302, a second set of features of the training set 302, etc.). For example, system 300 may train a model to generate a first trained model using the first set of features in the training set (e.g., sensor data from sensors 1-10, process chamber parameters 1-10, etc.) and to generate a second trained model using the second set of features in the training set (e.g., sensor data from sensors 11-20, process chamber parameters 11-20, etc.). In some embodiments, the first trained model and the second trained model may be combined to generate a third trained model (e.g., which may be a better predictor than the first or the second trained model on its own). In some embodiments, sets of features used in comparing models may overlap (e.g., first set of features being sensor data from sensors 1-15 and second set of features being sensors 5-20). In some embodiments, hundreds of models may be generated including models with various permutations of features and combinations of models.

At block 314, system 300 performs model validation (e.g., via validation engine 184 of FIG. 1) using the validation set 304. The system 300 may validate each of the trained models using a corresponding set of features of the validation set 304. For example, system 300 may validate the first trained model using the first set of features in the validation set (e.g., sensor data from sensors 1-10 or process chamber parameters 1-10) and the second trained model using the second set of features in the validation set (e.g., sensor data from sensors 11-20 or process chamber parameters 11-20). In some embodiments, system 300 may validate hundreds of models (e.g., models with various permutations of features, combinations of models, etc.) generated at block 312. At block 314, system 300 may determine an accuracy of each of the one or more trained models (e.g., via model validation) and may determine whether one or more of the trained models has an accuracy that meets a threshold accuracy. Responsive to determining that none of the trained models has an accuracy that meets a threshold accuracy, flow returns to block 312 where the system 300 performs model training using different sets of features of the training set. Responsive to determining that one or more of the trained models has an accuracy that meets a threshold accuracy, flow continues to block 316. System 300 may discard the trained models that have an accuracy that is below the threshold accuracy (e.g., based on the validation set).

At block 316, system 300 performs model selection (e.g., via selection engine 185 of FIG. 1) to determine which of the one or more trained models that meet the threshold accuracy has the highest accuracy (e.g., the selected model 308, based on the validating of block 314). Responsive to determining that two or more of the trained models that meet the threshold accuracy have the same accuracy, flow may return to block 312 where the system 300 performs model training using further refined training sets corresponding to further refined sets of features for determining a trained model that has the highest accuracy.

At block 318, system 300 performs model testing (e.g., via testing engine 186 of FIG. 1) using testing set 306 to test selected model 308. System 300 may test, using the first set of features in the testing set (e.g., sensor data from sensors 1-10), the first trained model to determine the first trained model meets a threshold accuracy. Determining whether the first trained model meets a threshold accuracy may be based on the first set of features of testing set 306. Responsive to accuracy of the selected model 308 not meeting the threshold accuracy, flow continues to block 312 where system 300 performs model training (e.g., retraining) using different training sets corresponding to different sets of features. Accuracy of selected model 308 may not meet threshold accuracy if selected model 308 is overly fit to the training set 302 and/or validation set 304. Accuracy of selected model 308 may not meet threshold accuracy if selected model 308 is not applicable to other data sets, including testing set 306. Training using different features may include training using data from different sensors, different manufacturing parameters, etc. Responsive to determining that selected model 308 has an accuracy that meets a threshold accuracy based on testing set 306, flow continues to block 320. In at least block 312, the model may learn patterns in the training data to make predictions. In block 318, the system 300 may apply the model on the remaining data (e.g., testing set 306) to test the predictions.

At block 320, system 300 uses the trained model (e.g., selected model 308) to receive current data 322 and determines (e.g., extracts), from the output of the trained model, output hazard data 324. Current data 322 may be manufacturing parameters and/or sensor data related to a process, operation, or action of interest. Current data 322 may be manufacturing parameters related to a process under development, redevelopment, investigation, etc. Current data 322 may include any data that may be used for predicting hazardous conditions in association with the process chamber. Current data 322 may include data associated with temperature of accessible surfaces of the process chamber, e.g., in preparation for a service operation. Current data 322 may include various sensor or parameter data related to chamber temperature, heater power, cooling system efficiency, lamps or other components that may act as heat sources or sinks, gas flow, ambient conditions, time since a previous condition for temperature of the chamber surfaces to settle, change, or reach equilibrium, etc. An action associated with the manufacturing equipment 124 of FIG. 1 may be performed in view of output hazard data 324. In some embodiments, current data 322 may correspond to the same types of features in the historical data used to train the machine learning model. In some embodiments, current data 322 corresponds to a subset of the types of features in historical data that are used to train selected model 308. For example, a machine learning model may be trained using a number of manufacturing chamber parameters, and configured to generate output based on a subset of the manufacturing chamber parameters.

In some embodiments, the performance of a machine learning model trained, validated, and tested by system 300 may deteriorate. For example, a manufacturing system associated with the trained machine learning model may undergo a gradual change or a sudden change. A change in the manufacturing system may result in decreased performance of the trained machine learning model. A new model may be generated to replace the machine learning model with decreased performance. The new model may be generated by altering the old model by retraining, by generating a new model, etc.

Generation of a new model may include providing additional training data 346. Generation of a new model may further include providing current data 322, e.g., data that has been used by the model to make predictions. In some embodiments, current data 322 when provided for generation of a new model may be labeled with an indication of an accuracy of predictions generated by the model based on current data 322. Additional training data 346 may be provided to model training of block 312 for generation of one or more new machine learning models, updating, retraining, and/or refining of selected model 308, etc.

In some embodiments, one or more of the acts 310-320 may occur in various orders and/or with other acts not presented and described herein. In some embodiments, one or more of acts 310-320 may not be performed. For example, in some embodiments, one or more of data partitioning of block 310, model validation of block 314, model selection of block 316, or model testing of block 318 may not be performed.

FIG. 3 depicts a system configured for training, validating, testing, and using one or more machine learning models. The machine learning models are configured to accept data as input (e.g., set points provided to manufacturing equipment, sensor data, etc.) and provide data as output (e.g., predictive data, risk reduction action data, classification data, etc.). Partitioning, training, validating, selection, testing, and using blocks of system 300 may be executed similarly to train a second model, utilizing different types of data. Retraining may also be performed, utilizing current data 322 and/or additional training data 346. Similar methods may be utilized for other types of models, e.g., to calibrate a physics-based model, to refine a rule-based on heuristic model, or the like.

FIGS. 4A-C are flow diagrams of methods 400A-C associated with training and utilizing machine learning models, according to certain embodiments. Methods 400A-C may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiment, methods 400A-C may be performed, in part, by predictive system 110. Method 400A may be performed, in part, by predictive system 110 (e.g., server machine 170 and data set generator 172 of FIG. 1, data set generator 272 of FIG. 2). Predictive system 110 may use method 400A to generate a data set to at least one of train, validate, or test a machine learning model, in accordance with embodiments of the disclosure. Methods 400B-C may be performed by predictive server 112 (e.g., predictive component 114) and/or server machine 180 (e.g., training, validating, and testing operations may be performed by server machine 180). In some embodiments, a non-transitory machine-readable storage medium stores instructions that when executed by a processing device (e.g., of predictive system 110, of server machine 180, of predictive server 112, etc.) cause the processing device to perform one or more of methods 400A-C.

For simplicity of explanation, methods 400A-C are depicted and described as a series of operations. However, operations in accordance with this disclosure can occur in various orders and/or concurrently and with other operations not presented and described herein. Furthermore, not all illustrated operations may be performed to implement methods 400A-C in accordance with the disclosed subject matter. In addition, those skilled in the art will understand and appreciate that methods 400A-C could alternatively be represented as a series of interrelated states via a state diagram or events.

FIG. 4A is a flow diagram of a method 400A for generating a data set for a machine learning model, according to some embodiments. Referring to FIG. 4A, in some embodiments, at block 401 the processing logic implementing method 400A initializes a training set T to an empty set.

At block 402, processing logic generates first data input (e.g., first training input, first validating input) that may include one or more of sensor, manufacturing parameters, etc. In some embodiments, the first data input may include a first set of features for types of data and a second data input may include a second set of features for types of data (e.g., as described with respect to FIG. 3). Input data may include historical data and/or synthetic data in some embodiments. Input data may include historical sensor data, historical equipment parameter data, historical measured hazard data, historical simulation data (e.g., input data to a physics-based model and/or output synthetic hazard data from a physics-based model), etc.

In some embodiments, at block 403, processing logic optionally generates a first target output for one or more of the data inputs (e.g., first data input). In some embodiments, the input includes one or more indications of conditions that are associated with chamber hazards, and the target output may be measured or simulated hazard data connected to the input. In some embodiments, the first target output is predictive data, such as predictive hazard data.

At block 404, processing logic optionally generates mapping data that is indicative of an input/output mapping. The input/output mapping (or mapping data) may refer to the data input (e.g., one or more of the data inputs described herein), the target output for the data input, and an association between the data input(s) and the target output. In some embodiments, such as in association with machine learning models where no target output is provided, block 404 may not be executed.

At block 405, processing logic adds the mapping data generated at block 404 to data set T, in some embodiments.

At block 406, processing logic branches based on whether data set T is sufficient for at least one of training, validating, and/or testing a machine learning model, such as synthetic data generator 174 or model 190 of FIG. 1. If so, execution proceeds to block 407, otherwise, execution continues back at block 402. It should be noted that in some embodiments, the sufficiency of data set T may be determined based simply on the number of inputs, mapped in some embodiments to outputs, in the data set, while in some other embodiments, the sufficiency of data set T may be determined based on one or more other criteria (e.g., a measure of diversity of the data examples, accuracy, etc.) in addition to, or instead of, the number of inputs.

At block 407, processing logic provides data set T (e.g., to server machine 180) to train, validate, and/or test machine learning model 190. In some embodiments, data set T is a training set and is provided to training engine 182 of server machine 180 to perform the training. In some embodiments, data set T is a validation set and is provided to validation engine 184 of server machine 180 to perform the validating. In some embodiments, data set T is a testing set and is provided to testing engine 186 of server machine 180 to perform the testing. In the case of a neural network, for example, input values of a given input/output mapping (e.g., numerical values associated with data inputs 210) are input to the neural network, and output values (e.g., numerical values associated with target outputs 220) of the input/output mapping are stored in the output nodes of the neural network. The connection weights in the neural network are then adjusted in accordance with a learning algorithm (e.g., back propagation, etc.), and the procedure is repeated for the other input/output mappings in data set T. After block 407, a model (e.g., model 190) can be at least one of trained using training engine 182 of server machine 180, validated using validating engine 184 of server machine 180, or tested using testing engine 186 of server machine 180. The trained model may be implemented by predictive component 114 (of predictive server 112) to generate predictive data 168 for performing signal processing, to generate synthetic data 162, or for performing an action associated with hazards of manufacturing equipment 124.

FIG. 4B is a flow diagram of a method 400B for generating and utilizing process chamber hazard data, according to some embodiments. In general, operations of method 400B are directed toward determining temperature of a surface of a process chamber, and/or determining whether temperature of the process chamber satisfies a threshold condition for a technician to perform one or more operations on the process chamber, such as service, maintenance, etc. In general, other conditions of the chamber may be applicable to aspects of method 400B, such as electrical charge remaining in one or more components with electrical capacitance, mechanical motion of one or more components such as rotational speed of a turbo pump, or the like. Corresponding hazard input data and hazard output data may be utilized in such cases.

At block 409, processing logic optionally obtains user selection of a surface of the process chamber. For example, a particular surface of interest may be selected via a virtual reality or augmented reality interface. A particular surface of interest may be selected via a virtual reality or augmented reality headset. A particular portion of a surface may be selected, e.g., a particular point of interest, such as an area of a surface that a technician may be likely to touch during a service operation in association with the process chamber.

At block 410, processing logic obtains first data indicative of a temperature of a first component of the process chamber. The first data may include any combination of data available that may indicate a temperature condition of the process chamber. The first data may include any combination of data available that may be related to hazardous conditions of the chamber, such as temperatures of surfaces that may cause burns if touched. The first data may include a set point of one or more heaters (e.g., temperature set points, power supply set points, or the like). The first data may include parameters of one or more elements acting as a heat source or heat sink (e.g., heaters, lamps, plasma sources, cooling systems, gas flow systems, etc.). The first data may include ambient conditions, such as temperature and/or atmospheric conditions proximate the process chamber. The first data may include time elapsed since a previous temperature state, e.g., the first data may be used to model evolution of hazardous conditions of a process chamber through time. The first data may include measured temperature data, e.g., from one or more temperature sensors disposed within the process chamber, within the process tool, proximate one or more components of manufacturing equipment, etc.

At block 412, processing logic processes the first data using a trained machine learning model. The trained machine learning model receives the first data as input. The trained machine learning model generates output including second data indicative of a temperature of a surface of the process chamber. The surface may be an exterior surface of the process chamber. The surface may be a surface that is likely to be touched by a technician, e.g., during a service operation, maintenance operation, cleaning operation, or the like.

At block 414, processing logic displays an augmented reality overlay including a visual indication of the temperature of the surface to the user. In some embodiments, a virtual reality display may be utilized. A virtual or augmented reality display may display a color-coded temperature scale on one or more surfaces of the process chamber, e.g., ranging from blue indicating cooler temperatures to red indicating hot temperatures. The visual indications of hazards (e.g., temperatures) may be presented via a headset, e.g., an augmented reality headset.

At block 416, processing logic optionally obtains a first indication of a safe-to-service condition of one or more components or systems of the process chamber. The save-to-service condition may be associated with a particular target service, e.g., a target service may be associated with a number of components, safety checks, interlocks, or the like related to operations performed for the target service. The safe-to-service condition may include temperatures of one or more surfaces that may be touched by a technician while performing a target service. In some embodiments, the safe-to-service condition may be based on a number of hazard conditions, including temperature conditions, electrical conditions, mechanical motion (e.g., robot motion) conditions, and/or the like.

At block 418, processing logic provides a safe-to-service alert to the user based on the first indication of the safe-to-service condition. The safe-to-service alert may be provided via the headset or another display device associated with the user. At block 420, processing logic optionally causes performance of a risk reduction action in view of the output of the trained machine learning model. The risk reduction action may further be performed in view of additional inputs, e.g., additional inputs that indicate that it is safe to perform one or more operations in association with the process chamber. The risk reduction action may include adjusting one or more components of the process chamber, such as adjusting the components to enable service. For example, one or more locking mechanisms may be disengaged, enabling service operations to be performed by a technician.

FIG. 4C is a flow diagram of a method 400C for generating a trained machine learning model for determining hazard conditions of a process chamber, according to some embodiments. As with method 400B, the operations of method 400C are presented in association with chamber temperature data, but other hazard data may be utilized with appropriate adjustments to data described in method 400C.

At block 430, processing logic optionally generates first data. Generation of the first data may include measuring, synthesizing, calculating, or otherwise generating data related to hazardous conditions of a process chamber. The first data may include indications related to temperature conditions of a process chamber. The first data may include temperature measurements, such as by one or more temperature sensors within the process chamber. The first data may include ambient condition of the process chamber. The first data may include time elapsed since a previous chamber state, e.g., time elapsed since a previous temperature set point was achieved, time elapsed since a previous substrate processing operation was performed, or the like. The first data may include conditions of a heat source or heat sink of the process chamber, such as a set point (e.g., manufacturing equipment parameter).

At block 432, processing logic optionally generates second data. The second data may include target output, associated with the first data as training input. The second data may include hazard conditions of the process chamber. The second data may include temperature data of one or more surfaces of the process chamber. Generating the second data may include performing temperature measurements of one or more surfaces of the process chamber, e.g., via an IR temperature measurement device. Generating the second data may include performing temperature measurements at a number of temperature conditions, e.g., a number of sets of equipment parameters or settings. Generating the second data may include providing input data to a model, e.g., a physics-based model of the process chamber. Generating the second data may include providing input data to a model calibrated using temperature measurement data. The physics-based model may be configured to provide solutions (e.g., numerical simulations) to physics-based equations in association with hazards of the process chamber. The physics-based model may be configured to provide solutions based on heat transfer equations.

At block 434, process logic obtains the first data indicative of temperature of a first component of the process chamber in a first plurality of temperature conditions. The first data may include any combination of data types discussed in connection with block 430. At block 436, process logic obtains the second data indicative of a temperature of a surface of the process chamber at the first plurality of temperature conditions.

At block 438, process logic trains a machine learning model to predict surface temperature of the process chamber by providing the first data as training input and the second data as target output.

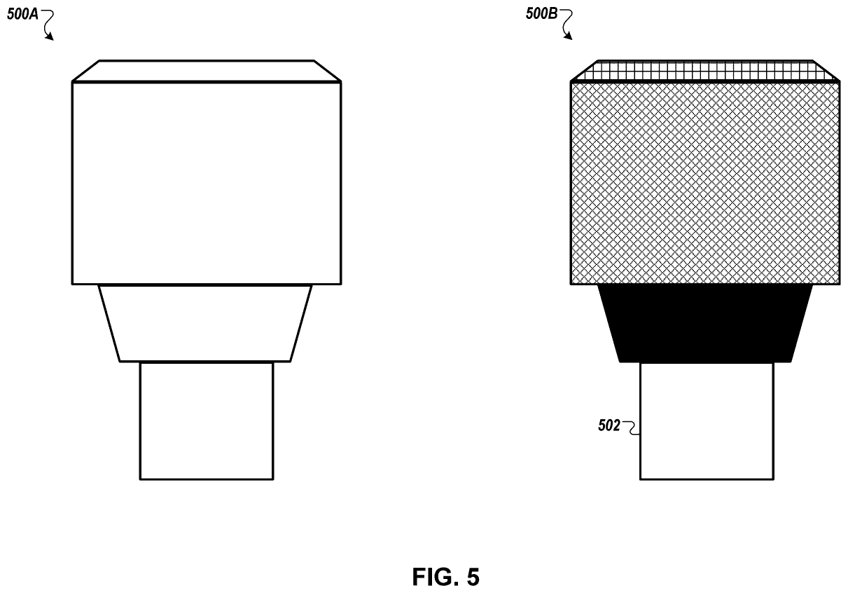

FIG. 5 depicts various exterior surfaces of a process chamber, including a representation 500A of the process chamber and a thermal overlay 500B of the process chamber, according to some embodiments. Representation 500A includes various surfaces of the process chamber, which may be of interest to a technician. Representation 500A may be a representation generated by a display, e.g., by a screen device or a virtual reality device. Representation 500A may instead represent the process chamber viewed through an augmented reality device, such as an augmented reality headset.

A display (e.g., an augmented reality headset display) may provide thermal overlay 500B over the representation 500A of the process chamber. Differences in overlay may indicate differences in underlying surfaces, including hazard level, type of hazard, relevance to a target service operation, or the like. In some embodiments, a normal representation of the process chamber may be viewed until a user selects a hazard overlay to be displayed. In some embodiments, various overlays may be utilized for depicting different hazards or different levels, e.g., different colors or patterns may be utilized for different temperatures of surfaces. In some embodiments, surfaces may be modeled as having a uniform hazard level, as depicted in FIG. 5. In some embodiments, individual surfaces may be represented with multiple hazard indications, e.g., coloring may indicate that a surface is cooler near the edges, and warmer in the middle.

In some embodiments, one or more surfaces (e.g., of the process chamber or of other objects included in a field of view of a virtual and/or augmented reality device) may not be included in a hazard overlay view. For example, lower surface 502 of thermal overlay 500B may not be included in a thermal overlay operation, as this surface may not be involved in servicing the chamber, may not be included in a set of surfaces associated with a target or selected service operation, may not be likely to be touched by a technician, may not be selected to be displayed by a user, or the like.

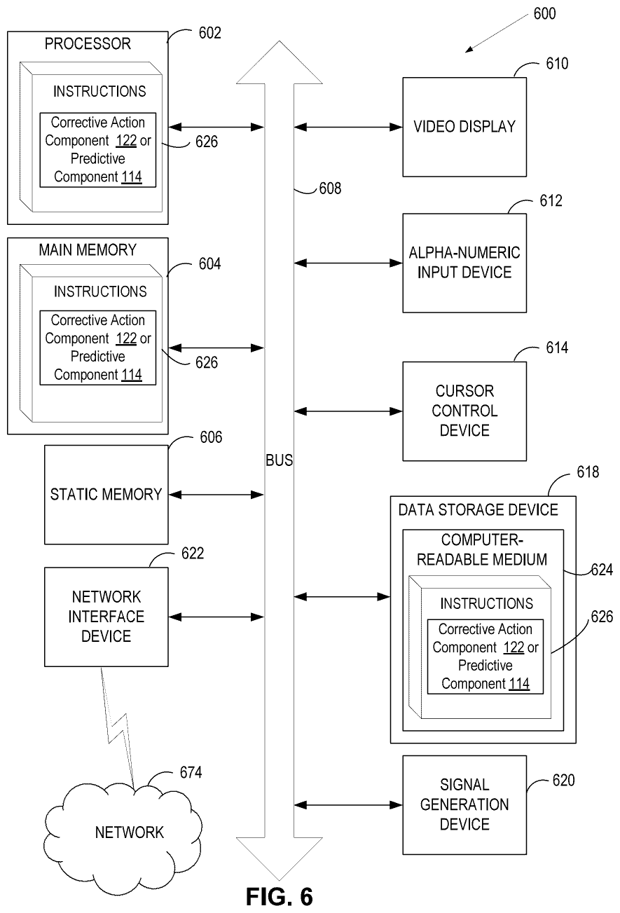

FIG. 6 is a block diagram illustrating a computer system 600, according to some embodiments. In some embodiments, computer system 600 may be connected (e.g., via a network, such as a Local Area Network (LAN), an intranet, an extranet, or the Internet) to other computer systems. Computer system 600 may operate in the capacity of a server or a client computer in a client-server environment, or as a peer computer in a peer-to-peer or distributed network environment. Computer system 600 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 600 may include a processing device 602, a volatile memory 604 (e.g., Random Access Memory (RAM)), a non-volatile memory 606 (e.g., Read-Only Memory (ROM) or Electrically-Erasable Programmable ROM (EEPROM)), and a data storage device 618, which may communicate with each other via a bus 608.

Processing device 602 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 600 may further include a network interface device 622 (e.g., coupled to network 674). Computer system 600 also may include a video display unit 610 (e.g., an LCD), an alphanumeric input device 612 (e.g., a keyboard), a cursor control device 614 (e.g., a mouse), and a signal generation device 620.

In some embodiments, data storage device 618 may include a non-transitory computer-readable storage medium 624 (e.g., non-transitory machine-readable medium) on which may store instructions 626 encoding any one or more of the methods or functions described herein, including instructions encoding components of FIG. 1 (e.g., predictive component 114, hazard determination component 122, model 190, etc.) and for implementing methods described herein.

Instructions 626 may also reside, completely or partially, within volatile memory 604 and/or within processing device 602 during execution thereof by computer system 600, hence, volatile memory 604 and processing device 602 may also constitute machine-readable storage media.

While computer-readable storage medium 624 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” “reducing,” “generating,” “correcting,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and embodiments, it will be recognized that the present disclosure is not limited to the examples and embodiments described. The scope of the disclosure should be determined with reference to the following claims, along with the full scope of equivalents to which the claims are entitled.

What is claimed is:

1. A method comprising:
obtaining, by a processing device, first data indicative of a temperature of a first component of a process chamber;
processing the first data using a trained machine learning model, wherein the trained machine learning model generates an output comprising second data indicative of a temperature of a surface of the process chamber; and
displaying an augmented reality overlay comprising a visual indication of the temperature of the surface to a user.

2. The method of claim 1, wherein the first data comprises a temperature set point of a heater of the process chamber.

3. The method of claim 1, wherein the first data comprises measured temperature data at a location within the process chamber, and the surface of the process chamber comprises an exterior surface of the process chamber.

4. The method of claim 1, further comprising:
obtaining a first indication of a safe-to-service condition of a component of the process chamber; and
providing a safe-to-service alert to the user based on the first indication of the safe-to-service condition and the temperature of the surface of the process chamber.

5. The method of claim 1, further comprising obtaining a user selection of the surface, and displaying the temperature of the surface responsive to obtaining the user selection, wherein the visual indication of the temperature of the surface comprises a color overlay to the surface.

6. The method of claim 1, wherein the first data comprises indications of one or more of:
ambient conditions proximate the process chamber;
time elapsed since a previous process chamber temperature state;
conditions of a heat source of the process chamber; or
conditions of a heat sink of the process chamber.

7. The method of claim 1, wherein the augmented reality overlay is displayed via an augmented reality headset device.

8. A method comprising:
obtaining, by a processing device, first data indicative of temperature of a first component of a process chamber in a first plurality of temperature conditions;
obtaining second data indicative of a temperature of a surface of the process chamber at the first plurality of temperature conditions; and
training a machine learning model to predict surface temperature of the process chamber by providing the first data as training input and the second data as target output.

9. The method of claim 8, further comprising performing temperature measurements of the temperature of the surface of the process chamber at the first plurality of temperature conditions, wherein the second data comprises the measurements.

10. The method of claim 8, further comprising:
providing an indication of a first temperature condition of the process chamber to a physics-based model; and
obtaining output from the physics-based model, wherein the second data comprises the output.

11. The method of claim 10, wherein the physics-based model is based on equations describing heat transfer and temperature measurements of the surface of the process chamber at the first plurality of temperature conditions.

12. The method of claim 8, wherein the first data comprises a temperature set point of a heater of the process chamber.

13. The method of claim 8, wherein the first data comprises measured temperature data of a location within the process chamber, and the surface of the process chamber comprises an exterior surface of the process chamber.

14. The method of claim 8, wherein the first data comprises indications of one or more of:
ambient conditions proximate the process chamber;
time elapsed since a previous process chamber temperature state;
conditions of a heat source of the process chamber; or
conditions of a heat sink of the process chamber.

15. A non-transitory machine-readable storage medium storing instructions which, when executed, cause a processing device to perform operations comprising:
obtaining first data indicative of a temperature of a first component of a process chamber;
processing the first data using a trained machine learning model, wherein the trained machine learning model generates an output comprising second data indicative of a temperature of a surface of the process chamber; and
displaying a visual indication of the temperature of the surface to a user.

16. The non-transitory machine-readable storage medium of claim 15, wherein the first data comprises a temperature set point of a heater of the process chamber.

17. The non-transitory machine-readable storage medium of claim 15, wherein the first data comprises measured temperature data at a location within the process chamber, and the surface of the process chamber comprises an exterior surface of the process chamber.

18. The non-transitory machine-readable storage medium of claim 15, wherein the operations further comprise:
obtaining a first indication of a safe-to-service condition of a component of the process chamber; and
providing a safe-to-service alert to the user based on the first indication of the safe-to-service condition and the temperature of the surface of the process chamber.

19. The non-transitory machine-readable storage medium of claim 15, wherein the operations further comprise obtaining a user selection of the surface, and displaying the temperature of the surface responsive to obtaining the user selection, wherein the visual indication of the temperature of the surface comprises a color overlay to the surface.

20. The non-transitory machine-readable storage medium of claim 15, wherein the first data comprises indications of one or more of:
ambient conditions proximate the process chamber;
time elapsed since a previous process chamber temperature state;
conditions of a heat source of the process chamber; or
conditions of a heat sink of the process chamber.
